(19) United States
(12) Patent Application Publication
(10) Pub. No.: US 2007/0209835 A1
(43) Pub. Date: Sep. 13, 2007

(54) SEMICONDUCTOR DEVICE HAVING PAD STRUCTURE CAPABLE OF REDUCING FAILURES IN MOUNTING PROCESS

(76) Inventors: Hyeon-Ho Song, Seoul (KR); Chi-Young Choi, Seoul (KR)

Correspondence Address: F. CHAU & ASSOCIATES, LLC, 130 WOODBURY ROAD, WOODBURY, NY, 11797, US

(21) Appl. No.: 11/620,216

(22) Filed: Jan. 5, 2007

(30) Foreign Application Priority Data
Jan. 5, 2006 (KR) 2006-01423

(51) Int. Cl. H05K 7/02

(52) U.S. Cl. 174/541; 361/783; 257/691

(57) ABSTRACT

A semiconductor device includes a semiconductor chip comprising a semiconductor substrate including microelectronic devices, first interconnection lines disposed on the semiconductor substrate and electrically connected to the microelectronic devices, pads connected to the first interconnection lines, wherein the pads are disposed on an edge of the semiconductor chip, and an interconnection substrate disposed on the semiconductor substrate, wherein the interconnection substrate includes second interconnection lines connected to a part of the pads, wherein a maximum distance between the pads is less than half a length of one side of the semiconductor chip, and heights of the pads are substantially the same.

This application claims priority to Korean Patent Application No. 2006-01423, filed on Jan. 5, 2006, the contents of which are herein incorporated by reference in their entirety.

### BACKGROUND OF THE INVENTION

1. Technical Field

The present disclosure relates to a semiconductor device, and more particularly, to a semiconductor device including a pad structure capable of reducing failures in a mounting process.

2. Discussion of the Related Art

Mounting technology for attaching a semiconductor device on a substrate is used for electronic devices, such as household appliances, computers, communication devices, military equipment, aircraft and spacecraft components. The electronic devices may further include portable phones, digital cameras, personal digital assistances (PDAs), and thin film transistor liquid crystal displays (TFT LCDs).

Conventional surface mounting technology includes Package On Board (POB) technology in which a semiconductor device in a package state is attached on a substrate and Chip On Board (COB) technology in which a semiconductor device in a chip state is attached on a substrate. A tape automated bonding (TAB)-type tape interconnection substrate has also been used to mount a semiconductor device.

FIGS. 1A and 1B are diagrams for illustrating a conventional method of mounting a semiconductor device. FIG. 1A is a plan view of a pad structure of a semiconductor chip. FIG. 1B is a plan view of a tape interconnection substrate.

Referring to FIG. 1A, a conventional semiconductor chip CP includes a plurality of integrated circuit (IC) regions ICR1 to ICR5. Microelectronic devices including transistors can be disposed in the IC regions ICR1 to ICR5 and connected to one another by an interconnection structure. The interconnection structure may include first interconnection lines 11 and second interconnection lines 12. The first interconnection lines 11 connect the microelectronic devices with each other. The second interconnection lines 12 connect the first interconnection lines 11 with external electronic devices. The first interconnection lines 11 are disposed on a different level from the second interconnection lines 12. The first and second interconnection lines 11 and 12, are connected by via plugs.

The first interconnection lines 11 include a ring-type power line and a ring-type ground line, which are disposed on an edge of the semiconductor chip CP. The power and ground lines are connected to the second interconnection lines 12 by via plugs 50.

Pads 20 are disposed on end portions of the second interconnection lines 12 and electrically connect the second interconnection lines 12 with external electronic devices. The pads 20 are disposed on edges of two opposite sides S1 and S2 of the semiconductor chip CP to facilitate the electrical connection and use the two edge areas of the semiconductor chip CP. As a result, no pads are disposed on the remaining sides S3 and S4 of the conventional semiconductor chip CP.

Referring to FIG. 1B, a tape interconnection substrate 60 has a structure corresponding to the pad structure of the semiconductor chip CP shown in FIG. 1A. The tape interconnection substrate 60 includes a plurality of third interconnection lines 70, which are separated from each other, and an insulating structure 80, which physically supports the third interconnection lines 70 and electrically insulates the third interconnection lines 70 from each other. The third interconnection lines 70 include an external connection portion 61 connected to an external electronic device, an internal connection portion 62 connected to the pads 20, and an intermediate connection portion 63 for connecting the external and internal connection portions 61 and 62. Since the pads 20 are disposed on the two opposite sides S1 and S2 of the semiconductor chip CP, the tape interconnection substrate 60 corresponding to the pads 20 has an open Y shape.

The electrical connection of the tape interconnection substrate 60 with the semiconductor chip CP can be formed by melting and compressing the pads 20. Thus, each of the pads 20 can have solder bump structure that protrudes from the semiconductor chip CP. A distance between the tape interconnection substrate 60 and the semiconductor chip CP is determined by the height of the pad 20. To connect the pads 20 and the third interconnection lines 70, the insulating structure 80 has openings 90 exposing bottom surfaces of the third interconnection lines 70 in regions corresponding to the pads 20.

Since the pads 20 are not disposed on the entire edge of the semiconductor chip CP, a pressure applied to the semiconductor chip CP varies according to location during the compression of the pads 20. For example, a high pressure can be concentrated on the pads 20. The high pressure on the pads 20 may cause a stress that includes failures in a mounting process. The tape interconnection substrate 60 has a Y shape corresponding to the arrangement of the pads 20. Thus, a distance between the tape interconnection substrate 60 and the semiconductor chip CP may not be constant during the compression of the pads 20. When the distance between the tape interconnection substrate 60 and the semiconductor chip CP is not constant during the compression of the pads 20, scratches in the compression of the pads 20 and/or failures in a mounting process may occur. A sufficient compression margin may not be formed when the distance is not constant.

### SUMMARY OF THE INVENTION

An exemplary embodiment of the present invention provides a semiconductor device having a pad structure capable of reducing compression stress caused by concentration of a high pressure on pads.

An exemplary embodiment of the present invention provides a semiconductor device having a pad structure in which a distance between an interconnection substrate and a semiconductor chip is constant.

An exemplary embodiment of the present invention provides a semiconductor device having a pad structure and interconnection structure that can reduce a noise.

According to an exemplary embodiment of the present invention, a semiconductor device includes a semiconductor chip comprising a semiconductor substrate including microelectronic devices. First interconnection lines can be disposed on the semiconductor substrate and electrically connected to the microelectronic devices. Pads can be connected to the first interconnection lines and disposed on a edge of the semiconductor chip. An interconnection substrate can be disposed on the semiconductor substrate and may include second interconnection lines connected to a part of the pads. A maximum distance between the pads can be less than half a length of one side of the semiconductor chip, and heights of the pads can be substantially the same.

According to an exemplary embodiment of the present invention, the semiconductor chip may have a first side and a second side, which are opposite to each other, and a third side and a fourth side, which are vertical to the first and second sides and opposite to each other. The first interconnection lines may include a plurality of signal lines, a power line, and a ground line through which a signal voltage, a power voltage, and a ground voltage are applied, respectively. The signal lines may have end portions disposed on the first and second sides of the semiconductor chip, and each of the power line and the ground line may have a ring shape provided along the first through fourth sides of the semiconductor chip.

The pads may include signal pads of which at least on is disposed on the end portion of each of the signal lines, and at least one auxiliary pad disposed on one of the power line and the ground line. The signal pads may be electrically connected to the second interconnection lines, while the auxiliary pads may be electrically insulated from the second interconnection lines by a predetermined insulating layer.

The auxiliary pads may be disposed on the third and fourth sides of the semiconductor chip and formed to substantially the same thickness as the signal pads. Thus, a distance from the third and fourth sides of the semiconductor chip to the interconnection substrate may be substantially the same as a distance from the first and second sides of the semiconductor chip to the interconnection substrate.

According to an exemplary embodiment of the present invention, the interconnection substrate may be disposed along the edge of the semiconductor chip and may contact with the signal pads and the auxiliary pads. The pads may be solder bumps that protrude from the top of the semiconductor chip. Heights of the solder bumps may be substantially the same.

According to an exemplary embodiment of the present invention, the pads may include signal pads of which at least one is disposed on the end portion of each of the signal lines, and at least one auxiliary pad disposed on at least one of the first connection lines. The signal pads may be electrically connected to the second interconnection lines, while the auxiliary pads may be electrically insulated from the second interconnection lines by a predetermined insulating layer. The auxiliary pads may be disposed on the third and fourth sides of the semiconductor chip and formed to substantially the same thickness as the signal pads. Thus, a distance from the third and fourth sides of the semiconductor chip to the interconnection substrate may be substantially the same as a distance from the first and second sides of the semiconductor chip to the interconnection substrate.

### BRIEF DESCRIPTION OF THE DRAWINGS

Exemplary embodiments of the present invention can be understood more detail from the following description taken in conjunction with the accompanying drawings in which:

FIGS. 1A and 1B are diagrams for illustrating a conventional method of mounting a semiconductor device;

FIG. 2A is a plan view of a semiconductor chip used for mounting a semiconductor device according to an embodiment of the present invention;

FIG. 2B is a plan view of a pad structure of the semiconductor chip shown in FIG. 2A;

FIGS. 3A through 3C are cross sectional views of a pad and interconnection line according to embodiments of the present invention;

FIG. 4 is a plan view of an interconnection substrate used for mounting a semiconductor device according to an embodiment of the present invention;

FIGS. 5A through 7A are plan views of semiconductor chips used for mounting a semiconductor device according to embodiments of the present invention; and

FIGS. 5B through 7B are plan views of pad structures of the semiconductor chips shown in FIGS. 5A through 7A, respectively.

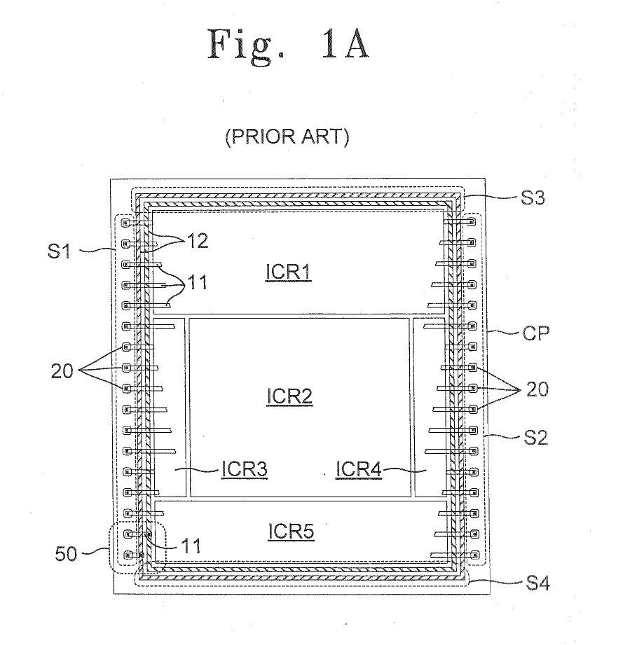

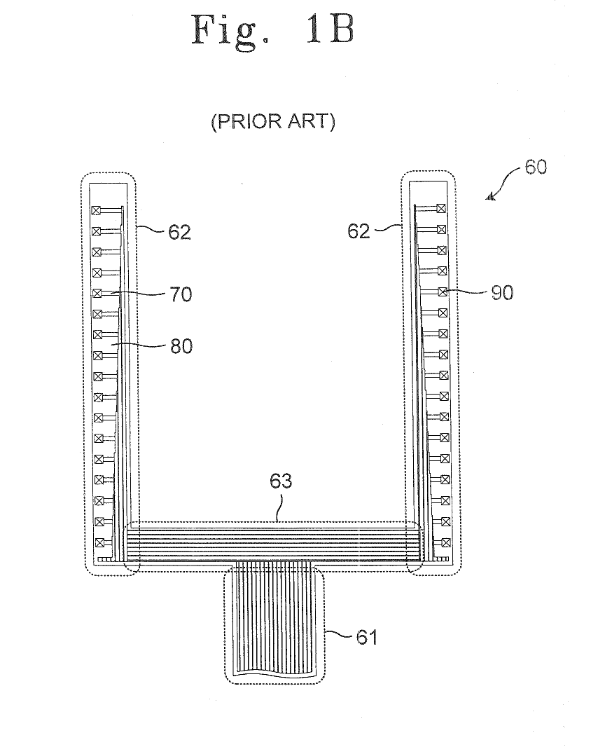

### DETAILED DESCRIPTION OF EXEMPLARY EMBODIMENTS

Exemplary embodiments of the present invention will be described below in more detail with reference to the accompanying drawings. The present invention may be embodied in many different forms and should not be constructed as limited to the embodiments set forth herein.

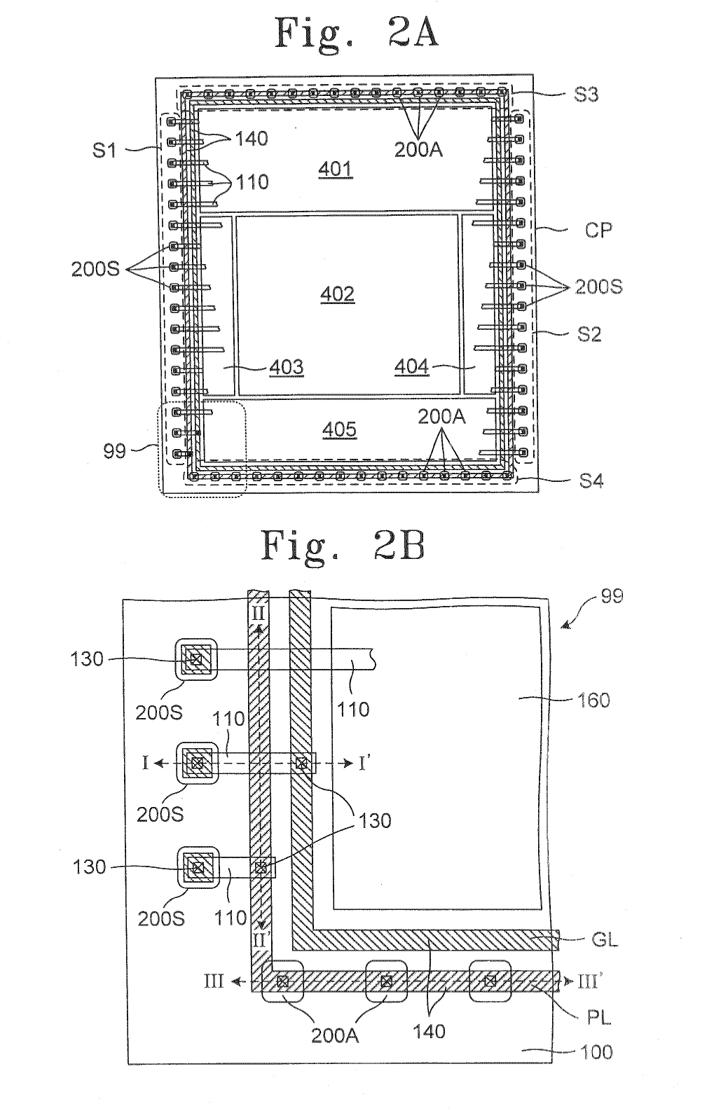

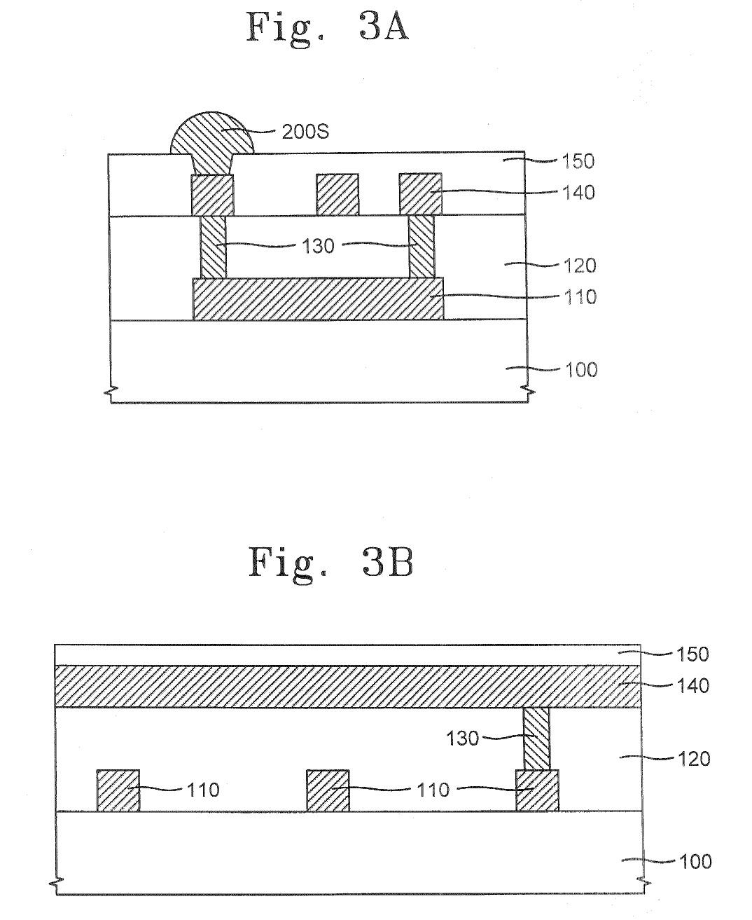

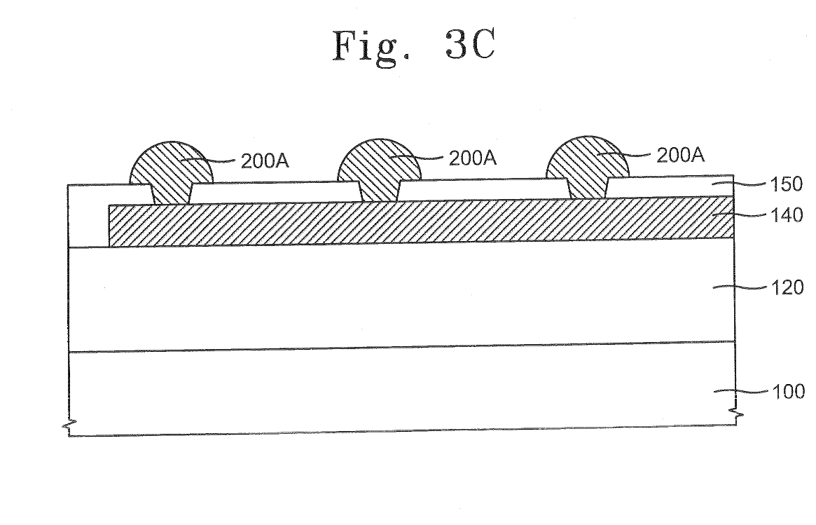

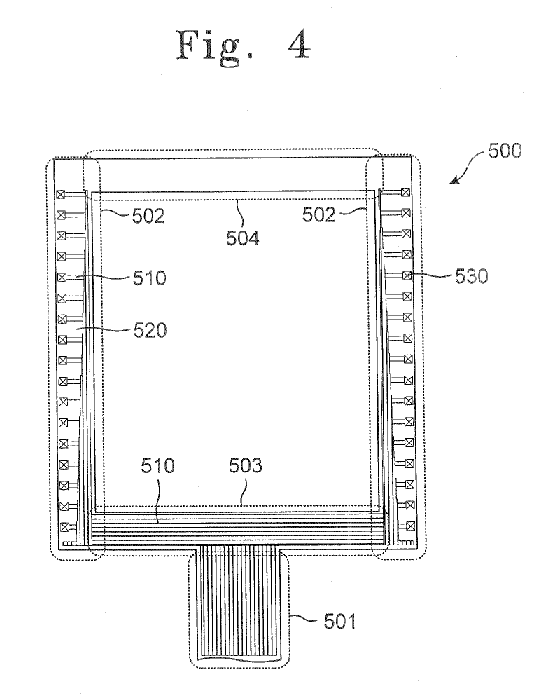

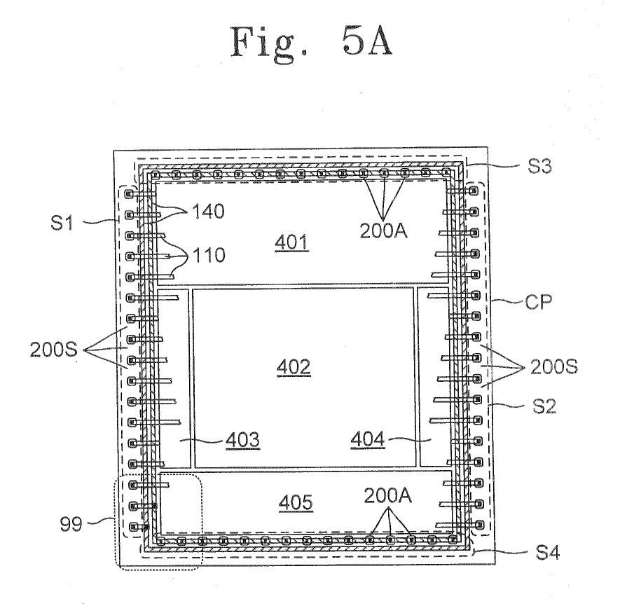

FIGS. 2A and 2B are plan views for illustrating a pad structure of a semiconductor chip used for mounting a semiconductor device according to an embodiment of the present invention. FIG. 2B is a magnified plan view of a region 99 shown in FIG. 2A. FIGS. 3A through 3C are cross sectional views of a pad and interconnection line according to embodiments of the present invention, which are taken along the dotted lines I-I′, II-II′, and III-III′ of FIG. 2B, respectively.

Referring to FIGS. 2A, 2B, and 3A through 3C, a semiconductor chip CP according to an embodiment of the present invention includes a plurality of integrated circuit (IC) regions 401 to 405. Microelectronic devices including, for example, transistors can be disposed in the IC regions 401 to 405 and connected to one another by an interconnection structure. The interconnection structure can be constructed to embody intrinsic functions of the semiconductor chip CP.

The interconnection structure may include first interconnection line 110 and second interconnection lines 140. The first interconnection lines 110 connect the microelectronic devices with each other. The second interconnection lines 140 connect the first interconnection lines 110 with external electronic devices. In an embodiment, the first interconnection lines 110 are disposed on a different level from the second interconnection lines 140. The first and second interconnection lines 110 and 140 can be connected by via plugs 130 in a predetermined region. The first and second interconnection lines 110 and 140 may comprise at least one of aluminum, copper, tungsten, tantalum nitride, or titanium nitride.

The first interconnection lines 110 are disposed on a semiconductor substrate 100 having the microelectronic devices. The second interconnection lines 140 are disposed on the resultant structure where the first interconnection lines 110 are provided. An interlayer dielectric layer (ILD) 120 is interposed between the first interconnection lines 110 and the second interconnection lines 140. Thus, the second interconnection lines 140 may intersect the first interconnection lines 110 without an electrical connection. The first interconnection lines 110 can be connected to the second interconnection lines 140 by the via plugs 130. The via plugs 130 can be formed through the ILD 120. For example, as illustrated in FIG. 2B, a power line PL and a ground line GL, which constitute the second interconnection lines 140, can be connected to the first interconnection lines 110, respectively, by the via plugs 130.

In an embodiment, a power supply voltage and a ground voltage are applied to the microelectronic devices through the power line PL and the ground line GL, respectively. Each of the power line PL and the ground line GL may have, for example, a square ring shape disposed along the edge of the semiconductor chip CP. The second interconnection lines 140 may further include a plurality of signal line through which a signal voltage is applied to the microelectronic devices.

Pads can be disposed on one end portions of the second interconnection lines 140 (e.g., the signal lines) such that the second interconnection lines 140 can be electronically connected to the external electronic devices. According to an embodiment of the present invention, the pads may include signal pads 200S and auxiliary pads 200A. The signal pads 200S can be used for an electrical connection. The auxiliary pads 200A can be used to reduce compression stress. The signal pads 200S can be disposed on two opposite sides S1 and S2 of the semiconductor chip CP to facilitate the electrical connection and use the two edge areas of the semiconductor chip CP. The auxiliary pads 200A can be disposed on the two sides S3 and S4 on which the signal pads 200S are not disposed, to disperse a pressure applied during a compression process. The pads of the semiconductor device according to an embodiment of the present invention can be disposed on the four sides S1 to S4 along the edge of the semiconductor chip CP.

The power line PL is disposed along the edge of the semiconductor chip CP. Thus, the auxiliary pads 200A may be disposed on the power line PL as illustrated in FIG. 2B. Since the auxiliary pads 200A increase the effective thickness of the power line PL, the resistance of the power line PL can decrease. As a result, RC delay and noise can be reduced.

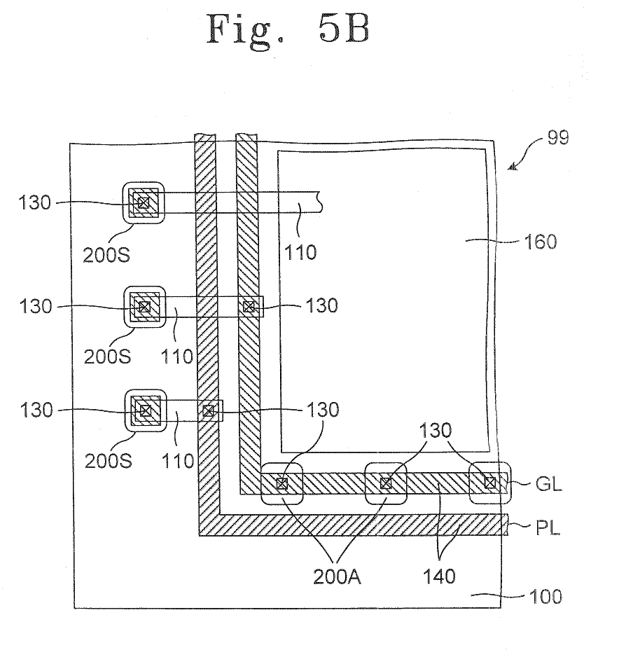

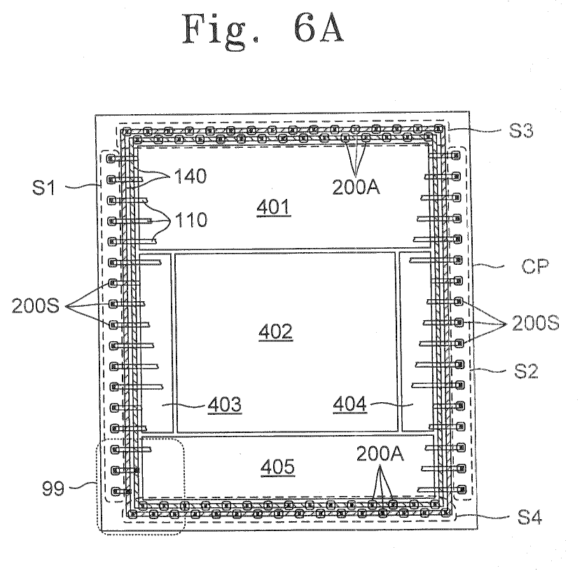

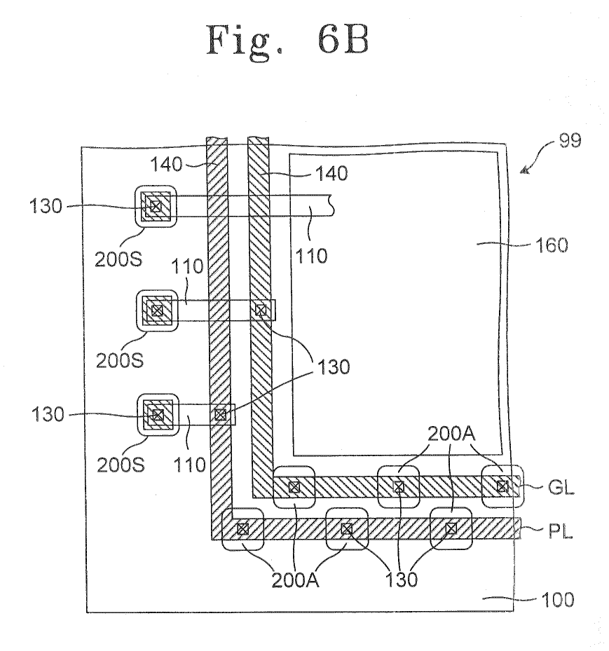

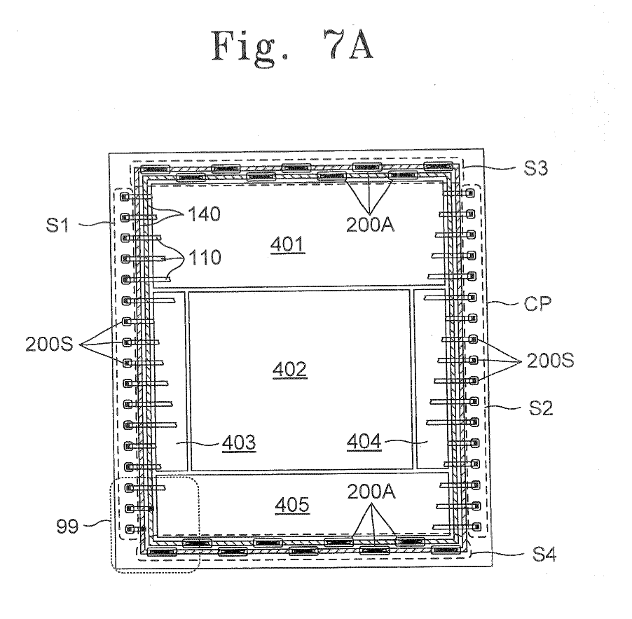

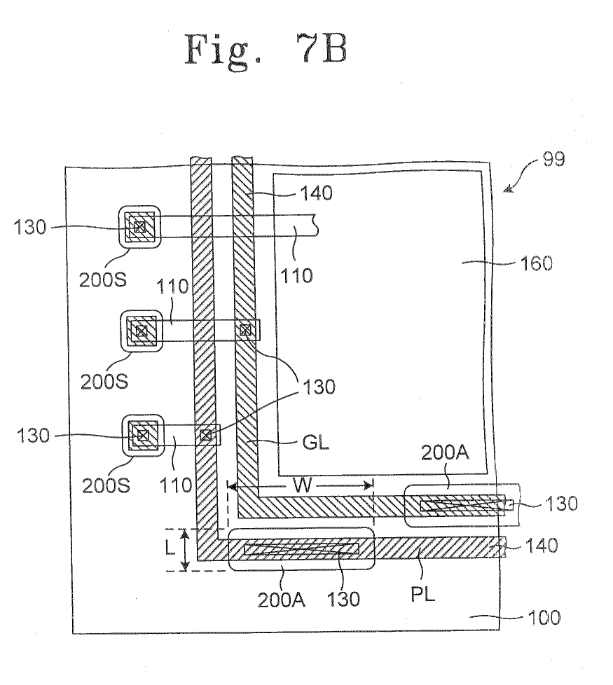

According to embodiments of the present invention, the arrangement and shape of the auxiliary pads 200A may be changed as illustrated in FIGS. 5A through 7A and 5B through 7B. FIGS. 5A through 7A are plan views for illustrating pad structures of semiconductor chips used for mounting a semiconductor device according to other embodiments for the present invention. FIGS. 5B through 7B are magnified plan views of regions 99 shown in FIGS. 5A through 7A, respectively. For example, the auxiliary pads 200A may be disposed on the ground line GL as illustrated in FIGS. 5A and 5B or disposed on the power line PL and the ground line GL as illustrated in FIGS. 6A and 6B. The planar shape of the auxiliary pads 200A may be changed. For instance, the auxiliary pads 200A may have a rectangular shape with a width W and a length L. The width W and length L can be different.

Since the auxiliary pads 200A are provided, for example, to reduce compression stress, the auxiliary pads 200A are not electrically connected to an interconnection substrate (500 of FIG. 4) disposed thereon. Thus, the auxiliary pads 200A according to an embodiment of the present invention may not be disposed on the power line PL and the ground line GL. The second interconnection lines 140 other than the power line PL and the ground line GL may be disposed on the edge of the semiconductor chip CP. The auxiliary pads 200A may be disposed on the second interconnection lines 140. In an embodiment, the auxiliary pads 200A are not electrically connected to the interconnection substrate 500. Thus, the use of the auxiliary pads 200A can reduce compression stress and noise. Therefore, the arrangement and shape of the auxiliary patterns 200A may be changed.

According to an embodiment of the present invention, the maximum distance from the signal pads 200S to the auxiliary pads 200A may be less than half the length of one side of the semiconductor chip CP and less than three times the maximum distance between the signal pads 200S.

Each of the signal and auxiliary pads 200S and 200A has a solder bump structure that produces from the top of the semiconductor chip CP. The signal and auxiliary pads 200S and 200A are provided on a protection layer 150 covering the second interconnection lines 140. In an embodiment, the protection layer 140 includes openings (not shown) exposing the surface of the second interconnection lines 140. The signal and auxiliary pads 200S and 200A are connected to the second interconnection lines 140 through the openings.

FIG. 4 is a plan view of an interconnection substrate used for mounting a semiconductor device according to an embodiment of the present invention.

Referring to FIG. 4, a tape interconnection substrate 500 according to an embodiment of the present invention includes a plurality of third interconnection lines 510, which are separated from each other, and an insulating structure 520, which physically supports the third interconnection lines 510 and electrically insulates each third interconnection line 510 from each other.

The tape interconnection substrate 500 may include an external connection portion 501, an internal connection portion 502, a first intermediate connection portion 503, and a second intermediate connection portion 504. The third interconnection lines 510, which are connected to the external electronic devices, are disposed on the external connection portion 501. The third interconnection lines 510, which are connected to the signal pads 200S, are disposed on the internal connection portion 502. To connect the signal pads 200S with the third interconnection lines 510, the insulating structure 520 has openings 530 exposing bottom surfaces of the third interconnection lines 510 in regions corresponding to the signal pads 200S. The openings 530 can be disposed in the internal connection portion 502. The third interconnection lines 510 that connect the external connection portion 501 with the internal connection portion 502 can be disposed on the first intermediate connection portion 503. The second intermediate connection portion 504 connects the internal connection portions 502.

According to the embodiments of the present invention, the tape interconnection substrate 500 can be disposed along the edge of the semiconductor chip CP. A uniform pressure can be applied to the edge of the semiconductor chip CP during a compression process of attaching the tape interconnection substrate 500 to the semiconductor chip CP. The pressure applied during the compression process can be dispersed by the auxiliary pads 200A.

The auxiliary pads 200A can have substantially the same structure as the signal pads 200S. For example, the auxiliary pads 200A and the signal pads 200S may be formed to substantially the same thickness (e.g., within a permissible error limit in a fabrication process). In an embodiment of the present invention, a distance between the tape interconnection substrate 500 and the semiconductor chip CP is constant on the edge of the semiconductor chip CP. As a result, scratches, an insufficient compression margin, and failures in a mounting process can be prevented.

According to the embodiments of the present invention, auxiliary patterns can be disposed on the edge of a semiconductor chip so that a distance between the semiconductor chip and an interconnection substrate can be constant. Thus, since a pressure applied during a compression process can be dispersed, compression stress can be reduced.

Since the effective thickness of interconnection lines constituting the semiconductor chip can increase due to the auxiliary patterns comprising, for example, a metallic material, the resistance of the interconnection lines can decrease. The decrease in the resistance of the interconnection lines leads to reductions of RC delay and noise in the semiconductor chip.

Although exemplary embodiments have been described with reference to the accompanying drawings, it is to be understood that the present invention is not limited to these precise embodiments but various changes and modifications can be made by one skilled in the art without departing from the spirit and scope of the present invention. All such changes and modifications are intended to be included within the scope of the invention as defined by the appended claims.

What is claimed is:

1. A semiconductor device comprising:
a semiconductor chip comprising a semiconductor substrate including microelectronic devices;
first interconnection lines disposed on the semiconductor substrate and electrically connected to the microelectronic devices;
pads connected to the first interconnection lines, wherein the pads are disposed on an edge of the semiconductor chip; and
an interconnection substrate disposed on the semiconductor substrate, wherein the interconnection substrate includes second interconnection lines connected to a part of the pads,
wherein a maximum distance between the pads is less than half a length of one side of the semiconductor chip, and heights of the pads are substantially the same.

2. The semiconductor device of claim 1, wherein the semiconductor chip includes a first side and a second side, the first side and the second side being opposite to each other, and a third side and fourth side, the third side and the fourth side being perpendicular with respect to the first and second sides and opposite to each other.

3. The semiconductor device of claim 2, wherein the first interconnection lines include a plurality of signal lines, a power line, and a ground line through which a signal voltage, a power voltage, and a ground voltage are applied, respectively.

4. The semiconductor device of claim 3, wherein the signal lines include end portions disposed on the first and second sides of the semiconductor chip, and each of the power line and the ground line are provided along the first through fourth sides of the semiconductor chip to form a ring shape.

5. The semiconductor device of claim 4, wherein the pads comprise:
signal pads of which at least one is disposed on an end portion of each of the signal lines; and
at least one auxiliary pad disposed on one of the power line and the ground line,
wherein the signal pads are electrically connected to the second interconnection lines, and the auxiliary pads are electrically insulated from the second interconnection lines by an insulating layer.

6. The semiconductor device of claim 5, wherein the auxiliary pads are disposed on the third and fourth sides of the semiconductor chip.

7. The semiconductor device of claim 6, wherein the auxiliary pads are formed to substantially the same thickness as the signal pads so that a distance from the third and fourth sides of the semiconductor chip to the interconnection substrate is substantially the same as a distance from the first and second sides of the semiconductor chip to the interconnection substrate.

8. The semiconductor device of claim 5, wherein the interconnection substrate is disposed along an edge of the semiconductor chip and physically contacts the signal pads and the auxiliary pads.

9. The semiconductor device of claim 1, wherein the pads comprise solder bumps that protrude from the semiconductor chip, and heights of the solder bumps are substantially the same.

10. The semiconductor device of claim 4, wherein the pads comprise:
signal pads, wherein at least one of the signal pads is disposed on an end portion of each of the signal lines; and
at least one auxiliary pad disposed on at least one of the first interconnection lines,
wherein the signal pads are electrically connected to the second interconnection lines, and the auxiliary pads are electrically insulated from the second interconnection lines by an insulating layer.

11. The semiconductor device of claim 10, wherein the auxiliary pads are disposed on the third and fourth sides of the semiconductor chip.

12. The semiconductor device of claim 11, wherein the auxiliary pads are formed to substantially the same thickness as the signal pads so that a distance from the third and fourth sides of the semiconductor chip to the interconnection substrate is substantially the same as a distance from the first and second sides of the semiconductor chip to the interconnection substrate.

13. A method of forming a semiconductor device, the method comprising:
forming semiconductor chip comprising a semiconductor substrate including microelectronic devices;
forming first interconnection lines on the semiconductor substrate;
connecting the first interconnection lines to the microelectronic devices;
forming pads on an edge of the semiconductor chip;
connecting the pads to the first interconnection lines; and
forming an interconnection substrate on the semiconductor substrate, wherein the interconnection substrate includes second interconnection lines connected to a part of the pads.

14. The method of claim 13, wherein a maximum distance between the pads is less than half a length of one side of the semiconductor chip, and heights of the pads are substantially the same.
